(19) United States
(12) Patent Application Publication
(10) Pub. No.: US 2025/0313455 A1
(43) Pub. Date: Oct. 9, 2025

(54) MICROELECTROMECHANICAL SYSTEMS DEVICE AND MANUFACTURING METHOD THEREOF

(71) Applicant: United Microelectronics Corp., Hsinchu (TW)

(72) Inventors: Jung Hao Chang, Taoyuan City (TW); Weng-Yi Chen, Hsinchu County (TW); Chang-Sheng Hsu, Hsinchu City (TW); Shih-Wei Li, Taoyuan City (TW)

(73) Assignee: United Microelectronics Corp., Hsinchu (TW)

(21) Appl. No.: 18/671,897

(22) Filed: May 22, 2024

(30) Foreign Application Priority Data
Apr. 3, 2024 (CN) 202410403528.7

(51) Int. Cl. B81C 1/00; B81B 3/00

(52) U.S. Cl. CPC B81C 1/00698; B81B 3/0086; B81B 2201/0257; B81B 2203/0127; B81B 2203/0315; B81B 2203/0346; B81B 2203/0353; B81C 2201/0128; B81C 2201/0174

(57) ABSTRACT

A microelectromechanical systems (MEMS) device including a substrate, a membrane layer and a plurality of patterned backplates is provided. The membrane layer is disposed on the substrate and has a plurality of corrugated structures. A top surface of the membrane layer has a rounded-corner feature, and a bottom surface of the membrane layer has a sharp-corner feature. The plurality of patterned backplates are disposed above the membrane layer. A manufacturing method of a MEMS device is also provided.

### CROSS-REFERENCE TO RELATED APPLICATION

This application claims the priority benefit of China application serial no. 202410403528.7, filed on Apr. 3, 2024. The entirety of the above-mentioned patent application is hereby incorporated by reference herein and made a part of this specification.

### BACKGROUND

### Technical Field

The disclosure relates to a microelectromechanical systems device and a manufacturing method thereof, and in particular to a microelectromechanical systems microphone and a manufacturing method thereof.

### Description of Related Art

In the microelectromechanical systems (MEMS) microphone products, the signal-to-noise ratio (SNR) and the low frequency roll-off (LFRO) are important indicators of whether they can enter the high-end market. Therefore, the current goal is to propose new designs of the MEMS microphone products in terms of the process and/or the structure, so as to achieve both the better SNR and the better LFRO.

### SUMMARY

The disclosure provides a microelectromechanical systems (MEMS) device having the better performance in terms of the signal-to-noise ratio (SNR) and the low frequency roll-off (LFRO).

According to some embodiments of the disclosure, a MEMS device including a substrate, a membrane layer and a plurality of patterned backplates is provided. The membrane layer is disposed on the substrate and has a plurality of corrugated structures. A top surface of the membrane layer has a rounded-corner feature, and a bottom surface of the membrane layer has a sharp-corner feature. The plurality of patterned backplates are disposed above the membrane layer.

The disclosure also provides a manufacturing method of a MEMS device. The manufactured MEMS device has the better performance in terms of the SNR and the LFRO.

According to another embodiments of the disclosure, the manufacturing method of the MEMS device includes the following steps. First, forming a first insulating layer on a substrate, wherein a first side of the substrate has a plurality of grooves, and a top surface of the first insulating layer has a recessed feature in the plurality of grooves. Next, forming a membrane layer on the first insulating layer, wherein the membrane layer has a plurality of corrugated structures, a top surface of the membrane layer has a rounded-corner feature, and a bottom surface of the membrane layer has a sharp-corner feature. After that, forming a plurality of patterned backplates on the first side of the substrate.

Based on the above, in the MEMS device and the manufacturing method thereof provided by the disclosure, by first forming the insulating layer on the substrate having grooves and then forming the membrane layer on the insulating layer, the membrane layer can include the plurality of corrugated structures having a specific profile. Therefore, the MEMS device provided by the disclosure can have the better performance in terms of the SNR and the LFRO.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIGS. 1A to 1I are cross-sectional schematic diagrams shown a flowchart of a manufacturing method of a microelectromechanical systems (MEMS) device according to an embodiment of the disclosure.

FIG. 2 is a scanning electron microscope (SEM) image of a membrane layer in a MEMS device according to an embodiment of the disclosure.

### DESCRIPTION OF THE EMBODIMENTS

The following examples are listed and described in detail with accompanying drawings, but the provided examples are not intended to limit the scope of the disclosure. In addition, the drawings are for illustrative purposes only and are not drawn to original size. To facilitate understanding, the same elements will be identified with the same symbols in the following description.

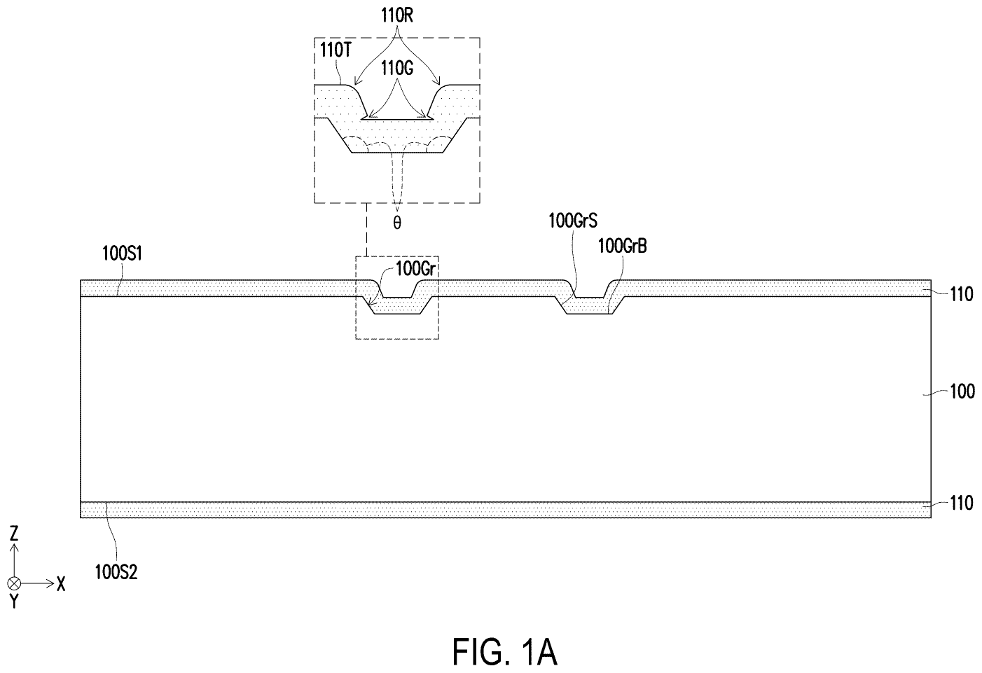

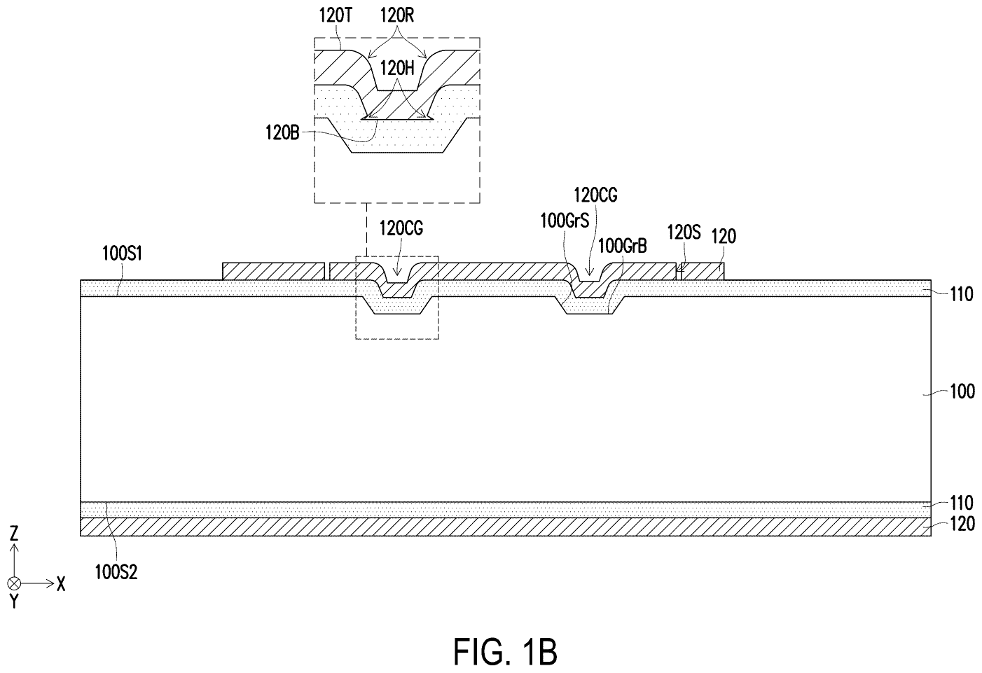

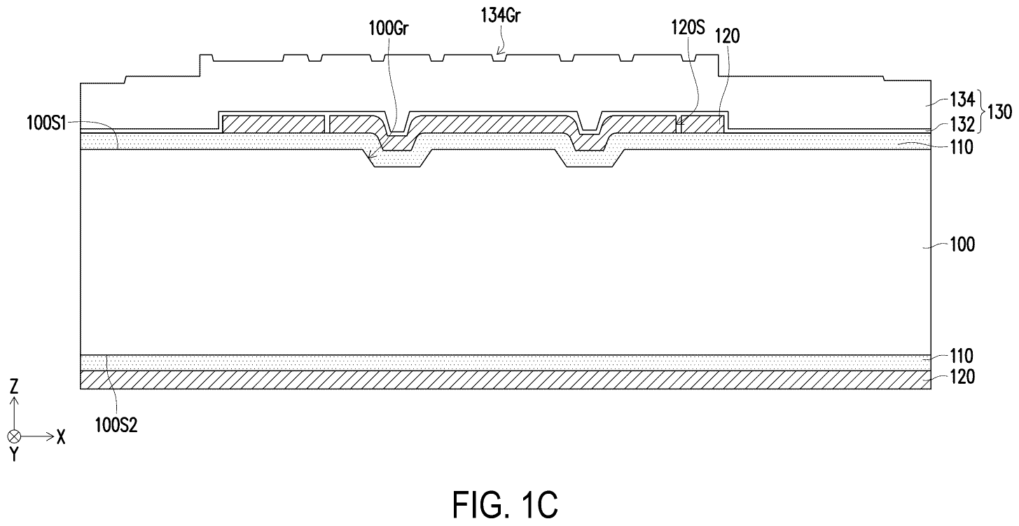

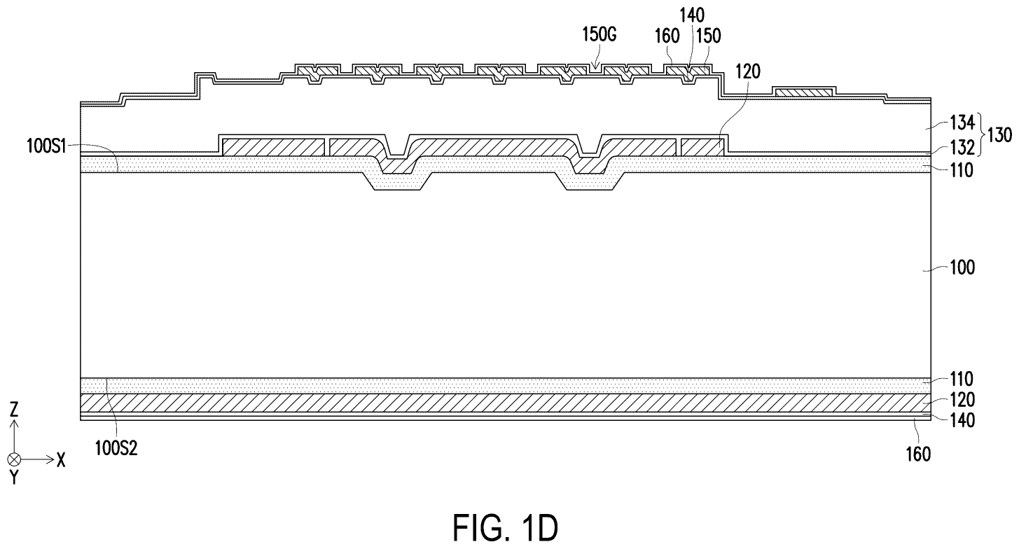

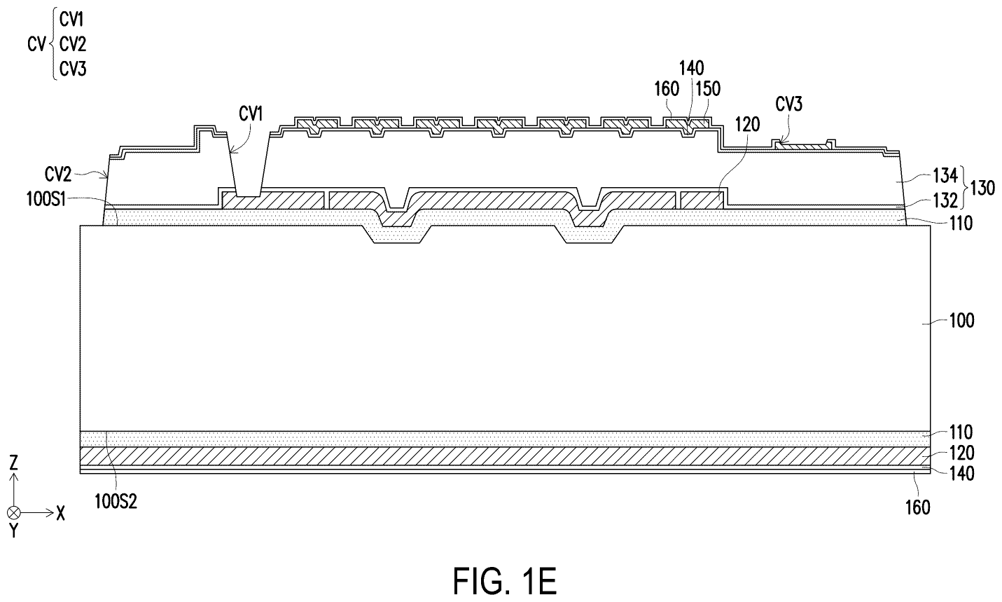

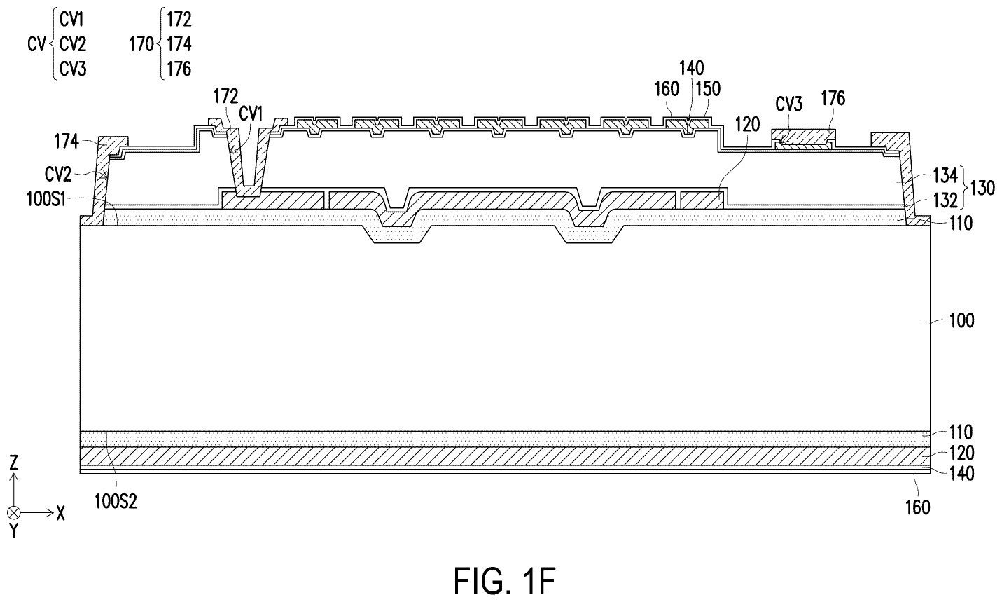

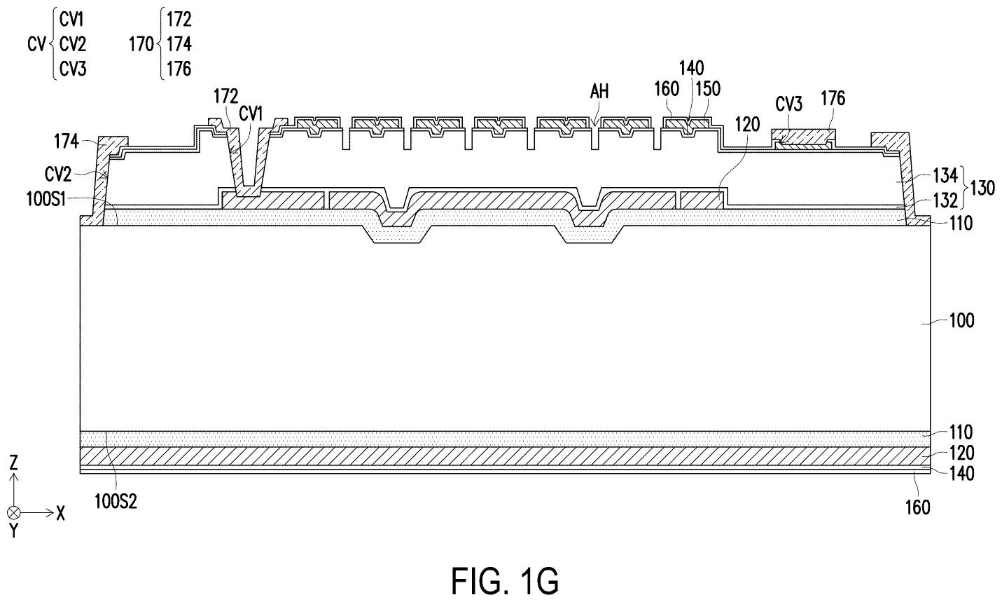

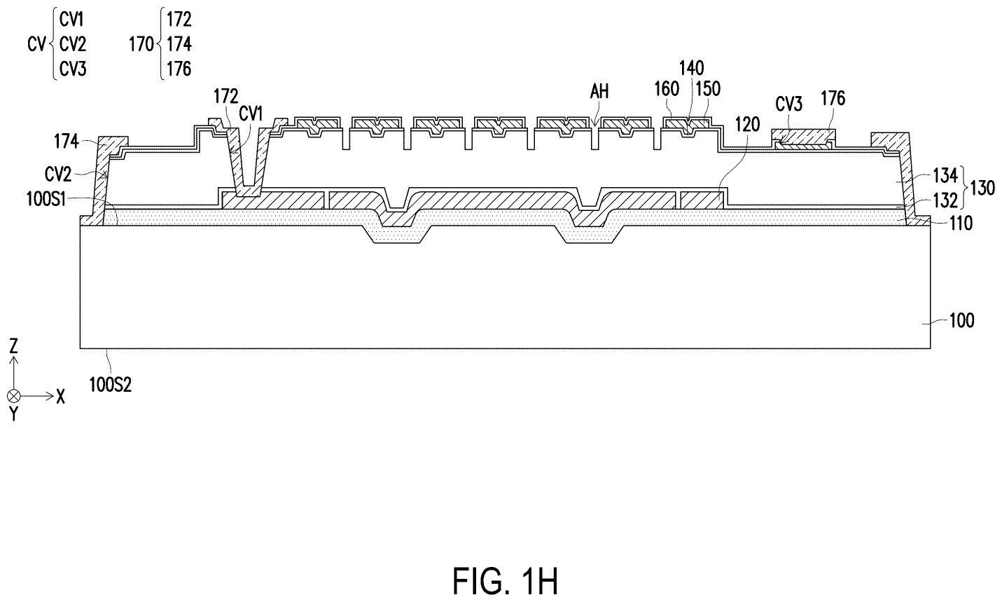

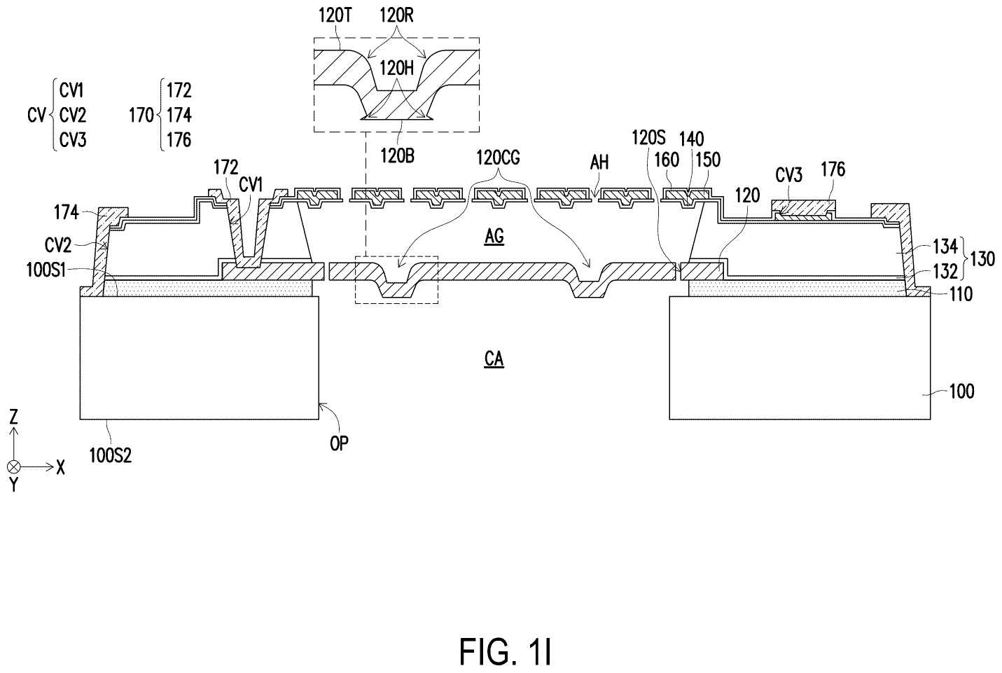

FIGS. 1A to 1I are cross-sectional schematic diagrams shown a flowchart of a manufacturing method of a microelectromechanical systems (MEMS) device according to an embodiment of the disclosure.

Referring to FIGS. 1A to 1I, in the present embodiment, a MEMS device 10 can be formed by performing the following steps, but the disclosure is not limited thereto.

Step (1): forming a first insulating layer 110 on a substrate 100, wherein a first side 100S1 of the substrate 100 has a plurality of grooves 100Gr.

Referring to FIG. 1A, in some embodiments, the substrate 100 includes a surface defined by a direction X and a direction Y and has the first side 100S1 and a second side 100S2, wherein the direction X can be perpendicular to the direction Y. The first side 100S1 of the substrate 100 is opposite to the second side 100S2 in a direction Z, wherein the direction Z can be a direction in which a thickness of the substrate 100 is measured from the first side 100S1 to the second side 100S2, and the direction Z can be perpendicular to the direction X and direction Y.

In some embodiments, the plurality of grooves 100Gr of the substrate 100 can be formed by performing an etching process, a drilling process, or a combination thereof, but the disclosure is not limited thereto. The groove 100Gr has a width along the direction X, and the width becomes smaller along the direction Z. In the present embodiment, an angle θ between a bottom surface 100GrB of the groove 100Gr and a side surface 100GrS of the groove 100Gr is 110° ˜120°, wherein the bottom surface 100GrB connects to the side surface 100GrS.

In some embodiments, the substrate 100 can be a semiconductor substrate, but the disclosure is not limited thereto. A material of the substrate 100 can include an elemental semiconductor, a compound semiconductor, an alloy semiconductor, or other suitable material. For example, the material of the substrate 100 can include silicon, germanium, indium antimonide, indium arsenide, indium phosphide, gallium nitride, gallium arsenide, gallium antimonide, lead telluride, or a combination thereof. In other embodiments, the substrate 100 can be a silicon-on-insulator (SOI) substrate.

The first insulating layer 110 can be formed on the first side 100S1 of the substrate 100 and the second side 100S2 of the substrate 100, but the disclosure is not limited thereto. In the present embodiment, the first insulating layer 110 is formed by performing a thermal oxidation process. Therefore, a top surface 110T of the first insulating layer 110 can have a rounded-corner feature 110R and a recessed feature 110G. In detail, the top surface 110T of the first insulating layer 110 can have the rounded-corner feature 110R located at a junction between a top surface of the substrate 100 and the bottom surface 100GrB of the groove 100Gr, and the top surface 110T of the first insulating layer 110 can have the recessed feature 110G located at a junction between the bottom surface 100GrB of the groove 100Gr and the side surface 100GrS of the groove 100Gr. Since the substrate 100 has a relatively low consumption rate at the above junctions during the thermal oxidation process, the rounded-corner feature 110R and the recessed feature 110G of the first insulating layer 110 can be formed, which causes the top surface 110T of the first insulating layer 110 can have a specific profile on the first side 100S1 of the substrate 100. It is worth mentioned that the top surface 110T of the first insulating layer 110 is a surface away from the substrate 100.

In some embodiments, a material of the first insulating layer 110 can include silicon oxide, but the disclosure is not limited thereto.

Step (2): forming a membrane layer 120 on the first insulating layer 110.

Referring to FIG. 1B, the membrane layer 120 can be formed on the first side 100S1 and the second side 100S2 of the substrate 100, but the disclosure is not limited thereto. In some embodiments, the membrane layer 120 can be formed by performing a chemical vapor deposition process. Since the top surface 110T of the first insulating layer 110 has the special profile, a top surface 120T of the membrane layer 120 can also have a rounded-corner feature 120R located at a junction between the top surface of the substrate 100 and the bottom surface 100GrB of the groove 100Gr, and a bottom surface 120B of the membrane layer 120 can have a sharp-corner feature 120H formed in the recessed feature 110G. It is worth noting that the top surface 120T of the membrane layer 120 is a surface away from the substrate 100, and the bottom surface 120B of the membrane layer 120 is a surface close to the substrate 100.

Based on the above, by first forming the first insulating layer 110 on the substrate 100 having the groove 100Gr and then forming the membrane layer 120 on the first insulating layer 110, the membrane layer 120 can have a plurality of corrugated structures 120CG. It is worth mentioned that FIG. 1B only shows two corrugated structures 120CG, but the disclosure is not limited thereto.

In the present embodiment, further performing a patterning process on the membrane layer 120 formed on the first side 100S1 of the substrate 100, so as to remove a portion of the membrane layer 120 and form a slit 120S, where the slit 120S penetrates the membrane layer 120.

In some embodiments, the membrane layer 120 is a conductive layer. A material of the membrane layer 120 can include polysilicon, but the disclosure is not limited thereto.

Step (3): forming a second insulating layer 130 on the first side 100S1 of the substrate 100.

Referring to FIG. 1C, in some embodiments, the second insulating layer 130 can be formed by performing the following process, but the disclosure is not limited thereto.

First, forming an insulating sub-layer 132 covering the membrane layer 120 on the first side 100S1 of the substrate 100. In some embodiments, the insulating sub-layer 132 can be formed by performing a chemical vapor deposition process, but the disclosure is not limited thereto. A material of the insulating sub-layer 132 can be an oxide. For example, the material of the insulating sub-layer 132 chemical vapor include tetraethoxysilane (TEOS), but the disclosure is not limited thereto.

After that, forming an insulating sub-layer 134 on the insulating sub-layer 132. In some embodiments, the insulating sub-layer 134 can also be formed by performing a chemical vapor deposition process, but the disclosure is not limited thereto. A material of the insulating sub-layer 134 can be the same as or similar to the material of the insulating sub-layer 132, which will be omitted herein.

Then, performed a patterning process on the insulating sub-layer 134 to form a plurality of grooves 134Gr. The plurality of grooves 134Gr of the insulating sub-layer 134 can be formed by performing an etching process, a drilling process, or a combination thereof, but the disclosure is not limited thereto.

Step (4): forming a first liner 140 on the substrate 100.

Referring to FIG. 1D, the first liner 140 can be formed on the first side 100S1 of the substrate 100 and the second side 100S2 of the substrate 100, but the disclosure is not limited thereto. In some embodiments, the first liner 140 can be formed by performing a chemical vapor deposition process, but the disclosure is not limited thereto. A material of the first liner 140 can have an etching selectivity different from an etching selectivity of the material of the second insulating layer 130, so as to be served as an etching stop when the second insulating layer 130 is subsequently removed. The material of the first liner 140 can include silicon nitride, but the disclosure is not limited thereto.

Step (5): forming a plurality of patterned backplates 150 on the first side 100S1 of the substrate 100.

Continuing to refer to FIG. 1D, in some embodiments, the plurality of patterned backplates 150 can be formed by performing the following process, but the disclosure is not limited thereto.

First, forming a backplate material layer (not shown) on the first liner 140 located on the first side 100S1 of the substrate 100. In some embodiments, the backplate material layer can be formed by performing a chemical vapor deposition process, but the disclosure is not limited thereto.

After that, performing a patterning process on the backplate material layer to form the plurality of patterned backplates 150, wherein there is a gap 150G between the adjacent patterned backplates 150.

In some embodiments, the plurality of patterned backplates 150 are conductive layers. A material of the patterned backplate 150 can include polysilicon, but the disclosure is not limited thereto.

Step (6): forming a second liner 160 on the substrate 100.

Continuing to refer to FIG. 1D, the second lining 160 can be formed on the first side 100S1 of the substrate 100 and the second side 100S2 of the substrate 100, and covers the plurality of patterned backplates 150 on the first side 100S1 of the substrate 100; however, the disclosure is not limited thereto. In some embodiments, the second liner 160 can be formed by performing a chemical vapor deposition process, but the disclosure is not limited thereto. A material of the second lining layer 160 can be the same as or similar to the material of the first lining layer 140, which will be omitted herein.

Step (7): forming a contact via CV on the first side 100S1 of the substrate 100.

Referring to FIG. 1E, in the present embodiment, the contact via CV includes a first contact via CV1, a second contact via CV2, and a third contact via CV3, which can be formed by performing a patterning process. For example, (1) the second liner 160, the first liner 140 and the second insulating layer 130 can be patterned to form the first contact via CV1 exposing a portion of the membrane layer 120; (2) the second liner 160, the first liner 140, the second insulating layer 130 and the first insulating layer 110 can be patterned to form the second contact via CV2 exposing a portion of the substrate 100; and (3) the second liner 160 can be patterned to form the third contact via CV3 exposing a portion of the patterned backplate 150.

In some embodiments, the contact via CV can be formed by performing the following process, but the disclosure is not limited thereto.

First, performing an etching process to remove a portion of the second liner 160, wherein the third contact via CV3 exposing the portion of the patterned backplate 150 and a contact via (not shown) exposing a portion of the second insulating layer 130 are formed. Since there are different etching selectivities between the second liner 160 and the patterned backplate 150 (and the second insulating layer 130), the patterned backplate 150 and the second insulating layer 130 can be used as an etching stop in this etching process.

After that, performing an etching process by using the second liner 160 as a mask to remove the second insulating layer 130 exposed by the second liner 160, wherein the first contact via CV1 exposing the portion of the membrane layer 120 is formed. In some embodiments, a part of the membrane layer 120 can be removed during the formation process of the first contact via CV1, but the disclosure is not limited thereto. It is worth mentioned that the exposed portion of the first insulating layer 110 is also removed in this etching process after the second insulating layer 130 is removed, so as to form the second contact via CV2 exposing the portion of the substrate 100.

Step (8): forming a contact layer 170 in the contact via CV.

Referring to FIG. 1F, in some embodiments, the contact layer 170 can be formed by performing the following process, but the disclosure is not limited thereto.

First, forming a contact material layer on the first side 100S1 of the substrate 100. In some embodiments, the contact material layer can be formed by performing a chemical vapor deposition process, but the disclosure is not limited thereto.

After that, performing a patterning process on the contact material layer to form the contact layer 170. The contact layer 170 can include a first contact layer 172, a second contact layer 174 and a third contact layer 176 respectively formed in the first contact via CV1, the second contact via CV2 and the third contact via CV3. Based on the above, the backplate 150 and the membrane layer 120 can be coupled through the formation of the contact layer 170.

In some embodiments, a material of the contact layer 170 can include suitable metal material, but the disclosure is not limited thereto.

Step (9): forming a plurality of acoustic holes AH on the first side 100S1 of the substrate 100.

Referring to FIG. 1G, in the present embodiment, the plurality of acoustic holes AH are formed by performing a patterning process on the second liner 160 disposed in the gap 150G. The patterning process can include an etching process, but the disclosure is not limited thereto. It is worth mentioned that the exposed portion of the insulating sub-layer 134 of the second insulating layer 130 can also be removed in this etching process after the second liner 160 disposed in the gap 150G is removed, but the disclosure is not limited thereto.

Step (10): performing a thinning process on the second side 100S2 of the substrate 100.

Referring to FIG. 1H, in some embodiments, the substrate 100 can be turned over before performing the thinning process on the second side 100S2 of the substrate 100, but the disclosure is not limited thereto. The thinning process performed on the second side 100S2 of the substrate 100 can include performing an etching process, a polishing process, or a combination thereof, but the disclosure is not limited thereto. It is worth mentioned that the first insulating layer 110, the membrane layer 120, the first liner 140 and the second liner 160 disposed on the second side 100S2 of the substrate 100 will be removed before performing the thinning process on the second side 100S2 of the substrate 100. However, the first insulating layer 110, the membrane layer 120, the first liner 140 and second liner 160 can also be removed in this thinning process, the disclosure is not limited thereto. In addition, a protective layer (not shown) can be formed on the first side 100S1 of the substrate 100 before performing the thinning process on the second side 100S2 of the substrate 100, but the disclosure is not limited thereto.

Step (11): forming a cavity CA in the substrate 100.

Referring to FIG. 1I, in some embodiments, an opening OP can be formed by performing a deep trench etching process on the second side 100S2 of the substrate 100, but the disclosure is not limited thereto. The formed opening OP exposes a portion of the first insulating layer 110. In the present embodiment, the portion of the first insulating layer 110 exposed by the opening OP of the substrate 100 is removed, so as to form the cavity CA.

Step (12): forming an air gap AG between the backplate 150 and the membrane layer 120.

Continuing to refer to FIG. 1I, in some embodiments, the substrate 100 can be turned over before forming the air gap AG, but the disclosure is not limited thereto. In the present embodiment, the second insulating layer 130 disposed between the backplate 150 and the membrane layer 120 can be wet-etched through the plurality of acoustic holes AH to form the air gap AG, but the disclosure is not limited thereto. It is worth mentioned that if the portion of the first insulating layer 110 exposed by the opening OP of the substrate 100 is not removed in the above step (11), the portion of the first insulating layer 110 exposed by the cavity CA can be also removed through the slit 120S, but the disclosure is not limited thereto.

At this point, the manufacturing method of the MEMS device 10 of the present embodiment is completed, but the manufacturing method of the MEMS device provided by the disclosure is not limited thereto.

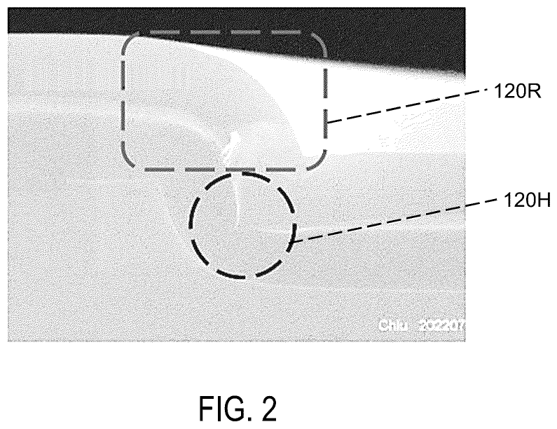

A structure of the MEMS device 10 of the present embodiment will be briefly introduced below with reference to FIGS. 11 and 2, but the disclosure is not limited thereto.

In the present embodiment, the MEMS device 10 includes the substrate 100, the membrane layer 120 and the plurality of patterned backplates 150.

The substrate 100 has the opening OP. It is worth mentioned that the rest of the introduction pertaining the substrate 100 can refer to the above embodiments, and will be omitted herein.

The membrane layer 120 is disposed on the substrate 100. A thickness of the membrane layer 120 along the direction Z is 2 angstroms to 10 angstroms, but the disclosure is not limited thereto. In the present embodiment, the membrane layer 120 has the plurality of corrugated structures 120CG. Further, the top surface 120T of the membrane layer 120 has the rounded-corner feature 120R near a crest of the corrugated structure 120CG, and the bottom surface 120B of the membrane layer 120 has the sharp-corner feature 120H near a trough of the corrugated structure 120CG. It is worth mentioned that the top surface 120T of the membrane layer 120 is a surface away from the substrate 100, and the bottom surface 120B of the membrane layer 120 is a surface close to the substrate 100.

In detail, referring to the SEM image in FIG. 2, which shows the rounded-corner feature 120R and the sharp-corner feature 120H of the membrane layer 120. As shown in FIG. 2, the top surface 120T of the membrane layer 120 has the rounded-corner feature 120R, and the bottom surface 120B of the membrane layer 120 has the sharp-corner feature 120H.

Through the design of the plurality of corrugated structures 120CG, the stress across the membrane layer 120 can be reduced when the membrane layer 120 undergoes the maximum strain, and the possibility of the membrane layer 120 being broken can be reduced, thereby improving the sensitivity of the MEMS device 10. Therefore, the SNR of the MEMS device 10 can be improved.

Furthermore, the membrane layer 120 of the present embodiment includes the slit 120S, wherein a width of the slit 120S along the direction X is less than 0.1 micron. The width of the slit 120S of the membrane layer 120 can be reduced through the design of the plurality of corrugated structures 120CG, thereby reducing the phenomenon of air leakage of the MEMS device 10. Therefore, the LFRO of the MEMS device 10 can be improved.

It is worth mentioned that the rest of the introduction pertaining the membrane layer 120 can refer to the above embodiments, and will be omitted herein.

The plurality of patterned backplates 150 are disposed above the membrane layer 120. A thickness of the plurality of patterned backplates 150 along the direction Z is 1 angstrom to 4 angstroms, but the disclosure is not limited thereto. In the present embodiment, each of the plurality of patterned backplates 150 has a bump structure facing the membrane layer 120. When operating the MEMS device 10, the membrane layer 120 approaches the patterned backplate 150. Therefore, the design of the bump structure can reduce the contact area between the membrane layer 120 and the patterned backplate 150, thereby reducing the possibility of adhesion of the membrane layer 120 to the patterned backplate 150.

It is worth mentioned that the rest of the introduction pertaining the plurality of patterned backplates 150 can refer to the above embodiments, and will be omitted herein.

In the present embodiment, the MEMS device 10 further includes the first insulating layer 110, the second insulating layer 130, the first liner 140, the second liner 160 and the contact layer 170.

The first insulating layer 110 is disposed between the membrane layer 120 and the substrate 100. In the present embodiment, the substrate 100, the first insulating layer 110 and the membrane layer 120 can define the cavity CA of the MEMS device 10. A thickness of the first insulating layer 110 along the direction Z is 2 angstroms to 10 angstroms, but the disclosure is not limited thereto. It is worth mentioned that the rest of the introduction pertaining the first insulating layer 110 can refer to the above embodiments, and will be omitted herein.

The second insulating layer 130 is disposed between the plurality of patterned backplates 150 and the membrane layer 120, and includes the insulating sub-layer 132 and the insulating sub-layer 134. A thickness of the insulating sub-layer 132 along the direction Z is 1 angstrom to 2 angstroms, and a thickness of the insulating sub-layer 134 along the direction Z is 15 angstroms to 30 angstroms, but the disclosure is not limited thereto. In the present embodiment, the membrane layer 120, the second insulating layer 130 and the plurality of patterned backplates 150 can define the air gap AG of the MEMS device 10, wherein a thickness of the air gap AG can be substantially the same as the sum of the thickness of the insulating sub-layer 132 and the thickness of the insulating sub-layer 134. It is worth mentioned that the rest of the introduction pertaining the second insulating layer 130 can refer to the above embodiments, and will be omitted herein.

The membrane layer 120 can be vibrated through the arrangement of the air gap AG and the cavity CA. In the present embodiment, the air gap AG and the cavity CA can be connected through the slit 120S of the membrane layer 120.

The first liner 140 is disposed between the plurality of patterned backplates 150 and the membrane layer 120, and covers a bottom surface of the plurality of patterned backplates 150. A thickness of the first liner 140 along the direction Z is 1 angstrom to 3 angstroms, but the disclosure is not limited thereto. It is worth mentioned that the rest of the introduction pertaining the first liner 140 can refer to the above embodiments, and will be omitted herein.

The second liner 160 is disposed on the plurality of patterned backplates 150 and covers the top surface and the side surface of the plurality of patterned backplates 150. A thickness of the second liner 160 along the direction Z is 1 angstrom to 3 angstroms, but the disclosure is not limited thereto. It is worth mentioned that the rest of the introduction pertaining the second liner 160 can refer to the above embodiments, and will be omitted herein.

The contact layer 170 is disposed on the second liner 160, and includes a first contact layer 172, a second contact layer 174 and a third contact layer 176. In the present embodiment, the first contact layer 172, the second contact layer 174 and the third contact layer 176 are respectively formed in the first contact via CV1, the second contact via CV2 and the third contact via CV3. Therefore, the patterned backplate 150 and the membrane layer 120 can be coupled through the contact layer 170. A thickness of the contact layer 170 along the direction Z is 8 angstroms to 25 angstroms, but the disclosure is not limited thereto. It is worth mentioned that the rest of the introduction pertaining the contact layer 170 can refer to the above embodiments, and will be omitted herein.

In summary, in the MEMS device and the manufacturing method thereof provided by the disclosure, by first forming the insulating layer on the substrate having grooves and then forming the membrane layer on the insulating layer, the membrane layer can include the plurality of corrugated structures having a specific profile. Therefore, the MEMS device provided by the disclosure can have the better performance in terms of the SNR and the LFRO, so as to increase the quality and the application range of electronic products including the MEMS device provided by the disclosure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A microelectromechanical systems (MEMS) device, including:
a substrate;
a membrane layer, disposed on the substrate and has a plurality of corrugated structures, wherein a top surface of the membrane layer has a rounded-corner feature, and a bottom surface of the membrane layer has a sharp-corner feature; and
a plurality of patterned backplates, disposed above the membrane layer.

2. The MEMS device according to claim 1, further including:
a first insulating layer, disposed between the membrane layer and the substrate, wherein the substrate, the first insulating layer and the membrane layer define a cavity of the MEMS device; and
a second insulating layer, disposed between the plurality of patterned backplates and the membrane layer, wherein the membrane layer, the second insulating layer and the plurality of patterned backplates define an air gap of the MEMS device.

3. The MEMS device according to claim 2, wherein the membrane layer includes a slit.

4. The MEMS device according to claim 3, wherein the air gap and the cavity are connected through the slit.

5. The MEMS device according to claim 1, further including:
a first liner, disposed between the plurality of patterned backplates and the membrane layer and covering a bottom surface of the plurality of patterned backplates;
a second liner, disposed on the plurality of patterned backplates and covering a top surface and a side surface of the plurality of patterned backplates; and
a contact layer, disposed on the second liner, wherein the plurality of patterned backplates and the membrane layer are coupled through the contact layer.

6. A manufacturing method of a microelectromechanical systems (MEMS) device, including:
forming a first insulating layer on a substrate, wherein a first side of the substrate has a plurality of grooves, and a top surface of the first insulating layer has a recessed feature in the plurality of grooves;
forming a membrane layer on the first insulating layer, wherein the membrane layer has a plurality of corrugated structures, a top surface of the membrane layer has a rounded-corner feature, and a bottom surface of the membrane layer has a sharp-corner feature; and
forming a plurality of patterned backplates on the first side of the substrate.

7. The manufacturing method of the MEMS device according to claim 6, further including following steps after forming the membrane layer and before forming the plurality of patterned backplates:
forming a second insulating layer on the first side of the substrate; and
forming a first liner on the first side of the substrate and a second side of the substrate, wherein the first side is opposite to the second side.

8. The manufacturing method of the MEMS device according to claim 6, further including following steps after forming the plurality of patterned backplates:
forming a second liner on the first side of the substrate and the second side of the substrate, wherein the second liner covers the plurality of patterned backplates on the first side of the substrate;
forming a contact via on the first side of the substrate; and
forming a contact layer in the contact via,
wherein the plurality of patterned backplates are coupled to the membrane layer through the contact layer.

9. The manufacturing method of the MEMS device according to claim 8, wherein the contact via includes a first contact via, a second contact via and a third contact via, the first contact via exposes a portion of the membrane layer, the second contact via exposes a portion of the substrate, and the third contact via exposes a portion of the plurality of patterned backplates.

10. The manufacturing method of the MEMS device according to claim 6, further including following steps after forming the plurality of patterned backplates:
forming a cavity in the substrate; and
forming an air gap between the plurality of patterned backplates and the membrane layer,
wherein the air gap and the cavity are connected through a slit of the membrane layer.
